(19) United States
(12) Patent Application Publication
(10) Pub. No.: US 2024/0344234 A1
(43) Pub. Date: Oct. 17, 2024

(54) AUTOMATED CONTROL OF SINGLE-CRYSTAL FIBER GROWTH PROCESS

(71) Applicant: Alcon Inc., Fribourg (CH)

(72) Inventors: Kevin Canzone, Coto de Caza, CA (US); Gisele Maxwell, Temecula, CA (US); Andrei Deev, Pasadena, CA (US)

(21) Appl. No.: 18/603,351

(22) Filed: Mar. 13, 2024

Related U.S. Application Data
(60) Provisional application No. 63/495,585, filed on Apr. 12, 2023.

(51) Int. Cl. C30B 15/26; C30B 15/06; C30B 15/16

(52) U.S. Cl. CPC C30B 15/26; C30B 15/06; C30B 15/16

(57) ABSTRACT

A method for growing a straight/non-tapered or a tapered high-transmission single-crystal fiber (SCF) using a fiber growth machine includes receiving, via an electronic control unit (ECU), a set of image data from a camera. The image data includes a first group of pixels of a feed fiber, a seed fiber, and a molten zone formed therebetween using a laser beam. The method includes identifying a feature of interest of the feed fiber, seed fiber, and/or molten zone within the first pixel group and locating position-identifying pixels within the feature of interest as a second pixel group. A horizontal position of the feed fiber is controlled via the ECU using the second pixel group while growing the fiber, including transmitting electronic control signals to actuators of the machine. An automated system for growing the SCF includes the camera configured and the ECU configured to perform the method.

### INTRODUCTION

The present disclosure relates to automated systems and methods for growing high-transmission optical fibers, e.g., a corundum such as sapphire or ruby, or another temperature-resistant monocrystalline or single-crystal fiber (SCF) suitable for use as a light propagation medium.

Laser beams are used in a myriad of scientific and medical applications of types requiring coherent beams of high-energy monochromatic light. For example, optical-quality lasers are frequently used to perform precision measurements and various ophthalmic surgeries. Such applications often require compact packaging and high optical transmission levels, along with low signal losses and high signal-to-noise ratios. These and other requirements can make the present optical fibers an ideal solution, as the contemplated optical fibers have relatively short lengths of about 0.05-2 meters, and small diameters of less than about 500 microns.

High-transmission optical-quality fibers can be grown in a laboratory setting. Such fibers, which are hereinafter referred to as SCFs for simplicity and illustrative consistency, may be fabricated via the process of laser-heated pedestal growth (LHPG) with the assistance of a fiber growth machine. During a typical LHPG-based process, concentrated heat energy from a directed laser beam is used to melt a tip of a crystalline or ceramic feed rod. A molten zone forms in this manner on a planar surface of position-controllable pedestal. A source crystal or seed fiber is then dipped into the molten zone and slowly drawn out under controlled tension. Laser-based melting of the feed rod continues concurrently with growth of the SCF to maintain the size of the molten zone. A resulting SCF, if grown under optimal conditions, will have various beneficial optical and structural qualities. However, it can be difficult to achieve such optimal growing conditions due to the slight positional variations or micromotion of the feed rod.

### SUMMARY

Disclosed herein is a computer-controlled system and accompanying method for monitoring and controlling the growth of a high-transmission, single-crystal fiber (SCF). The solutions set forth herein use machine vision capabilities and associated image processing techniques to automate the overall fiber growing process, reduce undesirable micromotion of the SCF during its growth to minimize internal strain, and thereby render the above-summarized laser-heated pedestal growth (LHPG) methodology more self-sufficient. The consistency and precision enabled by the present approach also results in SCFs with higher transmission capabilities without the need for manual operator control input.

An aspect of the present disclosure includes a method for monitoring and controlling the growth of a high-transmission SCF using a fiber growth machine. An embodiment of the method includes receiving digital image data from one or more cameras via an electronic control unit (ECU). The digital image data includes a first group of pixels of a seed fiber, a feed fiber, and a molten zone, with the molten zone formed between the seed and feed fibers using a laser beam. The method also includes identifying a feature of interest of the feed fiber, the seed fiber, and/or the molten zone within the first pixel group. The ECU performs this additional action.

One or more position-identifying pixels are then identified via the ECU within the feature of interest as a second pixel group. Thereafter, the method in this embodiment includes controlling a horizontal position of the feed fiber via the ECU using the second pixel group while growing the SCF, including transmitting electronic control signals to one or more actuators of the fiber growing machine.

An automated system is also disclosed herein for growing a high-transmission SCF. The automated system may include at least one camera and the above-summarized ECU. The camera is configured to output a set of digital image data inclusive of a first group of pixels of the feed fiber, seed fiber, and molten zone. The ECU, which is in communication with the camera(s), includes a processor and computer-readable storage medium on which is recorded an instruction set. The instruction set in turn is executable by the processor to cause the ECU to identify a feature of interest of the feed fiber, the seed fiber, and/or the molten zone within the first pixel group, and to thereafter locate one or more position-identifying pixels within the feature of interest as a second pixel group. The ECU then controls a horizontal position of the feed fiber using the second pixel group while growing the fiber, including transmitting electronic control signals to one or more actuators of the fiber growing machine.

The method in one or more embodiments may include identifying the feature of interest within the first group of pixels by identifying a saturated pixel cluster within the first group of pixels. The saturated pixel cluster has a threshold brightness level indicative of a location of the molten zone in the first group of pixels. The method may additionally include locating the one or more position-identifying pixels by identifying a center pixel of the saturated pixel cluster as a reference point, and subsequently controlling a horizontal position of the feed fiber in response to a positional variation of the reference point.

The method may also include maintaining a size and/or shape of the molten zone via the electronic position control signals, via the ECU, such that the reference point remains static.

An optional aspect of the disclosure includes varying the size and shape of the molten zone using the ECU, via control of the laser beam and/or a feed rate of the feed fiber, to thereby form a tapered profile in the fiber.

The method in accordance with one or more embodiments includes identifying the feature of interest by identifying respective edges of the feed fiber and the seed fiber within the first group of pixels, locating the position-identifying pixels includes using the respective edges to identify a common longitudinal centerline of the feed fiber and the seed fiber, and controlling the horizontal position of the feed fiber in response to a positional variation of the common longitudinal centerline. Identifying respective edges of the feed fiber and the seed fiber could optionally include using a Canny edge detection algorithm or another application-suitable edge detection process.

Receiving the set of image data from the at least one digital camera may include using a first camera to image a first optical axis of the feed fiber and a second camera to image a second optical axis of the feed fiber. The first optical axis of the feed fiber and the second optical axis of the feed fiber are mutually perpendicular in this non-limiting implementation.

Another aspect of the disclosure includes receiving, via the ECU, a trigger signal from an external device. The trigger signal is indicative of a requested initiation of a fiber growing process using the fiber growing machine. The method in such an embodiment may include requesting, via the ECU in response to the trigger signal, that the digital camera commences collection of the image data.

The fiber growth machine may include a translatable platform having a plurality of actuators collectively operable for moving the translatable platform with two horizontal translational degrees of freedom. Controlling the horizontal position of the feed fiber in turn may include controlling the actuators via the electronic position control signals.

The at least one camera may optionally include a first camera and a mirror. The first camera could be positioned on a first optical axis and operable for collecting portions of the image data on a first optical axis. The mirror may be positioned on a second optical axis that is orthogonally arranged with respect to the first optical axis. In this embodiment, the first camera is configured to collect another portion of the image data that is reflected off of the mirror.

Also disclosed herein is an automated system for monitoring and controlling growth of an SCF. An embodiment of the automated system includes a camera and an ECU. The camera outputs image data inclusive of a first group of pixels of a feed fiber, a seed fiber, and a molten zone. The molten zone is formed between the feed fiber and the seed fiber using a laser beam in a fiber growing machine. The ECU is in communication with the camera and includes a processor and computer-readable storage medium on which is recorded an instruction set. The instruction set being executable by the processor to cause the ECU to perform the above-summarized method.

The above-described features and advantages and other possible features and advantages of the present disclosure will be apparent from the following detailed description of various modes for carrying out the disclosure when taken in connection with the accompanying drawings.

### BRIEF DESCRIPTION OF THE DRAWINGS

FIG. 1 illustrates an exemplary embodiment of an automated system for monitoring and controlling growth of a single-crystal fiber (SCF) as set forth herein.

FIG. 2 is a simplified illustration of a representative molten zone during growth of an SCF.

FIG. 3 is a flow chart describing an embodiment of a method for monitoring and controlling growth of the SCF of FIG. 2 using the automated system shown in FIG. 1.

The solutions of the present disclosure may be modified or presented in alternative forms. Representative embodiments are shown by way of example in the drawings and described in detail below. However, inventive aspects of this disclosure are not limited to the disclosed embodiments. Rather, the present disclosure is intended to cover alternatives falling within the scope of the disclosure as defined by the appended claims.

### DETAILED DESCRIPTION

Embodiments of the present disclosure are described herein. It is to be understood, however, that the disclosed embodiments are merely examples and other embodiments can take various and alternative forms. The figures are not necessarily to scale. Some features could be exaggerated or minimized to show details of particular components. Therefore, specific structural and functional details disclosed herein are not to be interpreted as limiting, but merely as a representative basis for teaching one skilled in the art to variously employ the present disclosure.

As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

Certain terminology may be used in the following description for the purpose of reference only, and thus are not intended to be limiting. For example, terms such as “above” and “below” refer to directions in the drawings to which reference is made. Terms such as “front,” “back,” “fore,” “aft,” “left,” “right,” “rear,” and “side” describe the orientation and/or location of portions of the components or elements within a consistent but arbitrary frame of reference which is made clear by reference to the text and the associated drawings describing the components or elements under discussion. Moreover, terms such as “first,” “second,” “third,” and so on may be used to describe separate components. Such terminology may include the words specifically mentioned above, derivatives thereof, and words of similar import.

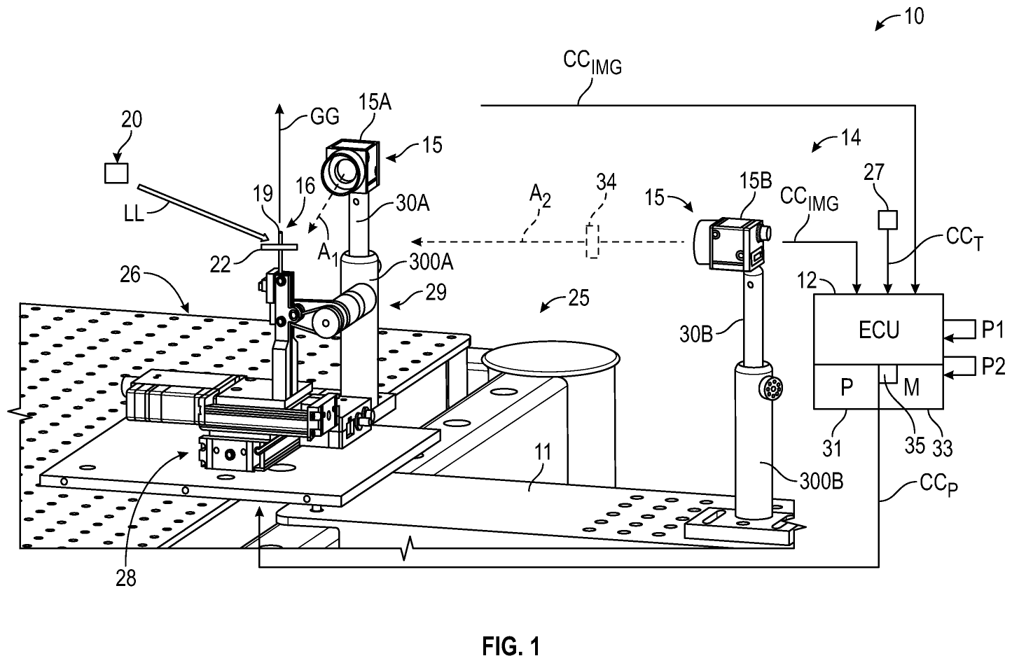

Referring to the drawings, wherein like reference numbers refer to like components, and beginning with FIG. 1, an automated system 10 in accordance with the disclosure includes an electronic control unit (ECU) 12 and an imaging system 14. The imaging system 14 includes at least one digital camera 15, e.g., respective first and second cameras 15A and 15B in the non-limiting setup of FIG. 1. Each digital camera 15 may be embodied as, e.g., a charged coupled device (CCD), a complementary metal oxide semiconductor (CMOS), an electron-multiplying CCD (EMCCD), or another application-suitable image sensor configured to output image data (CC_{IMG}) to the ECU 12.

The automated system 10 as described in detail herein is configured to monitor and control a fiber growth process of a single-crystal fiber (SCF) 16, e.g., sapphire or another application-suitable monocrystal. Fiber growth as contemplated herein is performed via a laser-heated pedestal growth (LHPG) process of the type summarized above. As appreciated in the art, such a process is performed by melting a tip of feed fiber 18 using a laser beam (LL) from a laser device 20. Molten material of the fiber 18 then accumulates on a pedestal 22 as a molten zone (MZ) 23. The SCF 16 is then carefully drawn from the molten zone 23 in the direction of arrow GG in a controlled manner. The resulting SCF 16 when properly formed may then be integrated into a wide range of devices, e.g., for spectroscopy, microscopy, ophthalmic or other laser surgeries, and the like.

The automated system 10 of the present disclosure may operate in conjunction with or be integrated with a fiber growing machine 25 to help optimize the overall fiber growth process when manufacturing the SCF 16. As appreciated by those skilled in the art, LHPG-capable fiber growing machines such as the fiber growing machine 25 illustrated in simplified form in FIG. 1 (enclosed growth chamber omitted) typically includes a table or other level workstation 11 and one or more of the laser devices 20, e.g., a CO₂ laser diode, Er:YAG, or another application-suitable laser type. The fiber growing machine 25 also includes a vertically-translatable pedestal 22 on which the SCF 16 is grown in the direction of arrow GG, and a horizontally-translatable platform apparatus 26 operatively connected to the pedestal 22.

The platform apparatus 26 in turn includes a plurality of actuators 28 providing positioning capabilities of the pedestal 22 with two horizontal translational degrees of freedom while another actuator 29 vertically translates the pedestal 22 in the direction of arrow GG. The first and second cameras 15A and 15B in this exemplary setup may be securely mounted to a respective tower 30A, 30B of a telescoping tower assembly 300A, 300B. In this configuration, first and second optical axes A₁ and A₂ of the respective first and second cameras 15A and 15B are arranged orthogonally to each other to image the SCF 16, feed fiber 18, seed fiber 19, and molten zone 23 as set forth below. As an alternative to using two digital cameras 15, one could position one or more mirrors 34 on the second optical axis A₂ for directing another portion of the image data (CC_{IMG}) to the remaining digital camera 15, e.g., the first camera 15A.

The platform apparatus 26 shown in the non-limiting construction of FIG. 1 is coupled to the pedestal 22 e.g., linear and/or rotary actuation devices such as electric motors, belts, ball screw assemblies, etc. The actuators 28 in turn are collectively operable for translating the platform 22. During operation of the fiber growing machine 25, even the slightest of positional variations in the pedestal 22 and the platform apparatus 28 can lead to undesirable “wobble” or other micromotion of the feed fiber 18. As such micromotion can affect the transmission quality of the SCF 16, the present solutions are directed toward minimizing such variation. The accompanying reduction in strain and overall improvement in transmission efficiency accomplished by the ECU 12 of FIG. 1, informed in real-time by machine vision-based feedback from the camera system 15 as set forth below, is thus intended to improve upon the general state of the art relating to LHPG-based growth of SCFs.

As part of the contemplated monitoring and control strategy, the ECU 12 ultimately controls the horizontal position of the feed fiber 18. This occurs by controlling the position of the above-noted actuators 28, 29 via electronic position control signals (CC_{P}). As contemplated herein, the image data (CC_{IMG}) is inclusive of a first pixel group pixels (P1) of the feed fiber 18, the seed fiber 19, and the molten zone 23. The ECU 12 then processes the received set of image data (CC_{IMG}) to identify, from among the first pixel group (P1), a characteristic second pixel group (P2) as described below. The ECU 12 thereafter uses the second pixel group (P2) in a particular manner to control operation of the fiber growing machine 25.

To that end, ECU 12 is in communication with the digital camera(s) 15, e.g., via a wired or wireless communications network or individual transfer conductors. The ECU 12 includes a processor (P) 31 and computer-readable storage medium or memory (M) 33 on which is recorded an instruction set 35. The instruction set 35 is executable by the processor 31 to cause the ECU 12 to process the image data (CC_{IMG}) to thereby identify a feature of interest of the feed fiber 18, the seed fiber 19, and/or the molten zone 23 within the first pixel group (P1). The ECU 12 then locates one or more position-identifying pixels within the identified feature of interest, with the position-identifying pixels forming the above-noted second pixel group (P2). The ECU 12 thereafter controls a horizontal position of the feed fiber 18 using the second pixel group (P2) while growing the SCF 18 via the fiber growing machine 25, including transmitting the position control signals (CC_{P}) to one or more of the actuators 28, 29 of the fiber growing machine 25.

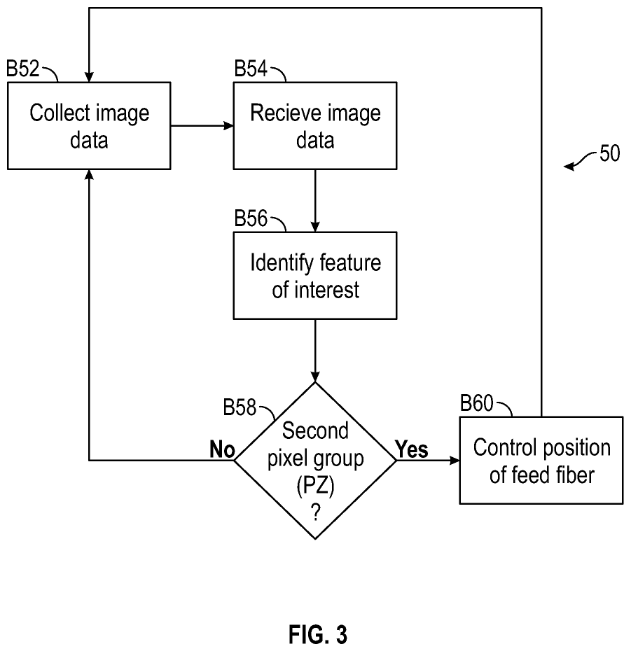

The ECU 12 shown schematically in FIG. 1 may be programmed in software and equipped in hardware, i.e., configured, to perform a method 100 (see FIG. 3) by executing the instruction set 35 as computer-readable instructions from its resident memory 33 using the processor 31. An external device 27 such as a button, dial, keyboard, keypad, or another suitably constructed human-machine interface may be manually activated to generate a trigger signal (CC_{T}), or the trigger signal (CC_{T}) could be autonomously generated. The trigger signal (CC_{T}) in turn may be indicative of a user-requested or autonomously-requested initiation of monitoring and automation using the automated system 10.

The memory 33 may include tangible non-transitory memory, e.g., optical, magnetic, flash, or other types of read only memory, along with application-sufficient amounts of random-access memory, electrically-erasable programmable read only memory, etc. The processor 31 for its part may be constructed from various combinations of Application Specific Integrated Circuit(s) (ASICs), Field-Programmable Gate Arrays (FPGAs), electronic circuits, central processing units, microprocessors, and the like. Non-transitory components of the memory may store computer-readable instructions for controlling operation of the fiber growing machine 25 and the automated system 10 described herein.

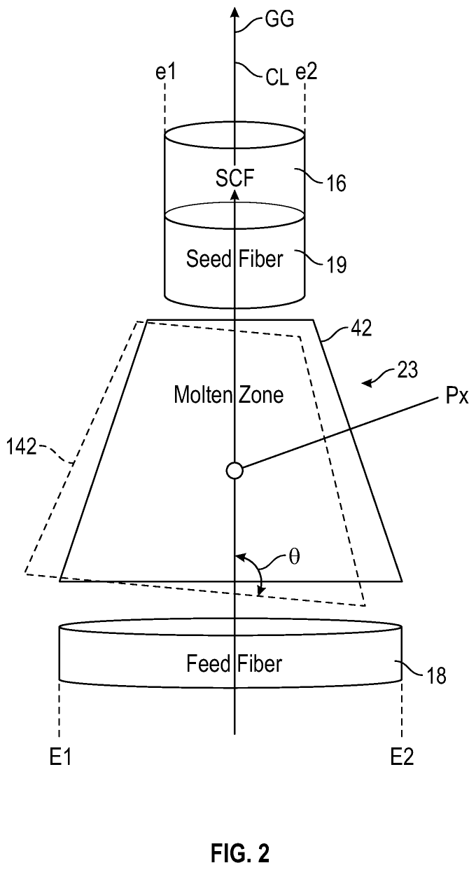

Referring to FIG. 2, the molten zone 23 is shown in a simplified schematic manner and having an outer perimeter 42. As appreciated by those skilled in the art, the size of a typical molten zone 23 is quite small, e.g., about 200 microns (μ) or less proximate the seed fiber 19 by about 600μ proximate the feed fiber 18. During its growth, the SCF 16 can exhibit micromotion in the form of wobble, with the changing position and orientation of the SCF 16 represented by outer perimeter 142. That is, a common longitudinal centerline (CL) of the SCF 16 and the feed fiber 18 may vary slightly from true normal, as indicated by tilt angle (θ), thus imparting undesirable internal strain to the SCF 16 as noted above.

In order to identify the feature of interest, the ECU 12 may optionally identify a saturated pixel cluster within the first pixel group (P1). As appreciated in the art, SCFs tend to melt at very high temperatures, sometimes in excess of 2000° C. As a result, image pixels corresponding to the molten zone 23 will tend to be bright relative to surrounding pixels. The ECU 12 can therefore treat the location of a detected saturated pixel cluster as corresponding to the molten zone 23.

For instance, the ECU 12 illustrated in FIG. 1 could be programmed with a threshold brightness level that is characteristic or indicative of the molten zone 23. The ECU 12 could then perform a digital comparison on constituent image pixels or clusters thereof to determine if any have a brightness that equals or exceeds the threshold brightness level. Once the saturated pixel cluster has been located, the ECU 12 could thereafter locate any position-identifying pixels as the second pixel group (P2) noted above.

One approach for locating the position-identifying pixel(s) as the second pixel group (P2) includes identifying a center pixel (P_{X}) in the saturated pixel cluster corresponding to the molten zone 23. The center pixel (P_{X}) could thereafter be registered in memory as a zero point or reference position (P_{REF}). In such an embodiment, control of the horizontal position of the feed fiber 18 could occur via the ECU 12 in response to a positional variation of the reference position (P_{REF}) within the saturated pixel cluster. The ECU 12 can thereafter maintain a size and/or shape of the molten zone 23 via the electronic position control signals (CC_{P}) of FIG. 1 such that the reference position (P_{REF}) remains static.

An alternative or possibly concurrent approach, the ECU 12 could identify the feature of interest by identifying respective edges E1, E2 of the feed fiber 18 and e1, e2 the seed fiber 19 within the first pixel group. In such an implementation, the ECU 12 could locate the position-identifying pixels using the respective edges E1, E2, e1, and e2. Such an action would identify a common longitudinal centerline (CL) of the feed fiber 18 and the seed fiber 19. The ECU 12 in this case could stabilize the horizontal position of the feed fiber 18 in response to a positional variation of the common longitudinal centerline (CL).

The SCF 16 when formed in accordance with either aspect of the disclosure could have a non-tapered cross-sectional shape. However, the present teachings could also be used to form an SCF 16 having a tapered surface profile, e.g., a truncated hourglass shape. This effect could be achieved by varying the size and shape of the molten zone 23 in real-time via control of the laser device 20 and/or a feed rate of the feed fiber 18.

Referring now to FIG. 3, a method 50 is shown for monitoring and controlling growth of a high-transmission SCF 16 using the fiber growth machine 25 of FIG. 1. The method 50 is illustrated in simplified form as being organized into discrete logic blocks. Each logic block in turn represents a particular step, function, or subprocess that is to be performed via the ECU 12 of FIG. 1 when executing the present method 50.

The method 50 may commence after first setting up the growing process using the fiber growing machine 25 of FIG. 1. Growth could lead to formation of a straight SCF 16 or one having a tapered profile as disclosed above. That is, the ECU 12 could optionally control the laser device 20 and/or a feed rate of the feed fiber 16 to form a tapered profile in the SCF 16, as appreciated in the art, and thus the method 50 is not limited to the growth of straight SCFs 16.

As the SCF 16 begins to grow, the ECU 12 may initiate automatically or in response to receiving the trigger signal (CC_{T}) from the external device 27 (see FIG. 1), with the trigger signal (CC_{T}) being indicative of a user-requested or autonomously-requested initiation of monitoring and automation using the automated system 10 as described above. The method 50 thus commences in response to a request by ECU 12 that the digital cameras 15 illustrated in FIG. 1 commence collection of the image data (CC_{IMG}).

Beginning with block B52 (“Collect image data”), the method 50 includes collecting the digital image data (CC_{IMG}) of the feed fiber 18, the seed fiber 19, and the molten zone 23 of FIG. 2, with the latter being formed between the feed fiber 18 and the seed fiber 19 using the laser beam (LL) of FIG. 1. The digital camera(s) 15 then output the image data (CC_{IMG}) to the ECU 12. The method 50 thereafter proceeds to block B54.

Block B54 (“Receive image data”) includes receiving a set of image data (CC_{IMG}) from the digital camera(s) 15 via the ECU 12 of FIG. 1. The image data (CC_{IMG}) includes the first pixel group (P1) as noted above, i.e., image pixels of the feed fiber 18, the seed fiber 19/SCF 16, and the molten zone 23 of FIG. 2. Block B54 may entail using the first camera 15A of FIG. 1 to image along first optical axis A₁, and possibly using the second camera 15B (or the mirror(s) 34) to ultimately capture the image data (CC_{IMG}) along the second optical axis A₂. Optical axes A₁ and A₂ could be mutually perpendicular as described above. The method 50 thereafter proceeds to block B56.

Block B56 (“Identify feature of interest”) may entail identifying, via the ECU 12, a feature of interest of the feed fiber 18, the seed fiber 19/SCF 16, and/or the molten zone 23 within the first pixel group (P1) of FIG. 1. This action may include identifying a saturated pixel cluster within the first pixel group (P1), i.e., as bright pixels relative to a threshold brightness level indicative of a location of the molten zone 23 in the first pixel group (P1). In another implementation, identifying the feature of interest could include identifying respective edges E1, E2 of the feed fiber 18 and edges e1, e2 of the seed fiber 19/SCF 16 within the first pixel group (P1). From the identified edges, the ECU 12 could identify the position and tilt angle of the feed fiber 18 from true normal (relative to a horizontal plane of the platform 22 of FIG. 1) as the feed fiber 18 wobbles or strays toward the digital camera(s) 15. The ECU 12 can then use this information to control horizontal stability of the feed fiber 18. The method 50 then proceeds to block B58.

Block B58 (“Second pixel group?”) includes locating one or more position-identifying pixels within the feature of interest of block B56 as the second pixel group (P2). In the disclosed embodiment in which a saturated pixel cluster is used as the feature of interest, this action could entail locating any position-identifying pixels by identifying the center pixel (P_{X}) of FIG. 2 and using this as the reference point (P_{REF}).

Locating position-identifying pixels may also include using the respective edges (E1, E2, e1, e2) of FIG. 2 to identify the shared or common longitudinal centerline (CL) extending between the feed fiber 18 and the seed fiber 19/SCF 16. Locating the edges in this manner may occur via programmed operation of the ECU 12, e.g., using a Canny edge detection algorithm to locate such edges using an intensity gradient or another suitable image processing technique. Using edge detection, the ECU 12 is also able to see the shape of the “cone” of the molten zone 23, as will be appreciated in the art. The ECU 12 can also adjust the feed and laser energy to ensure the appearance of straight/linear cone edges rather than edges that are curved. Such an approach would improve the growth process, and can be automated using the approach described above. The method 50 proceeds to block B60 when one or more position-identifying pixels are successfully located within the feature of interest. The method 50 otherwise returns to block B52.

At block B60 (“Control position of feed fiber”), the ECU 12 depicted in FIG. 1 controls the horizontal position of the feed fiber 18 using the second pixel group from block B58 while growing the SCF 16. This action may entail transmitting the position control signals (CC_{P}) of FIG. 1 to the actuators 28, 29 of the fiber growing machine 25, and ultimately the position of the pedestal 22. Controlling the horizontal position of the feed fiber 18 could occur in response to a positional variation of the reference point (P_{REF}) of FIG. 2 within the saturated pixel cluster in one or more embodiments, e.g., in response to a positional variation of the common longitudinal centerline (CL). Additionally, the ECU 12 could maintain a size and shape of the molten zone 23 of FIG. 2 such that the reference point (P_{REF}) remains static.

Using the foregoing teachings, operator/growers would no longer be required to manually adjust parameters in a reactive manner when attempting to maintain control over the fiber growth process. As a result, implementation of the method 50 in conjunction with the automated system 10 reduces the variability in quality and consistency of the SCF 16. Thus, monitoring and control of an LHPG process to grow the SCF 16 as set forth above may be fully automated such that the process become self-sufficient, i.e., not requiring the presence of a human operator to ensure optimal resulting fiber qualities. These and other attendant benefits of the present disclosure will be readily appreciated by those skilled in the art now having the advantage of the present disclosure.

Embodiments shown in the drawings or the characteristics of various embodiments mentioned in the present description are not necessarily to be understood as being independent of each other. It is possible that each of the characteristics described in a given embodiment could be combined with one or more other desired characteristics from other embodiments, resulting in other embodiments not described in words or by reference to the drawings.

Accordingly, such other embodiments fall within the framework of the scope of the appended claims. The detailed description and the drawings are supportive and descriptive of the disclosure, but the scope of the disclosure is defined solely by the claims. While various modes and other embodiments for carrying out the claimed disclosure have been described in detail, various alternative designs and embodiments exist for practicing the disclosure defined in the appended claims.

1. A method for growing a single-crystal fiber (SCF) using a fiber growth machine having one or more actuators, the method comprising:
receiving, via an electronic control unit (ECU), a set of image data from at least one digital camera, wherein the image data includes a first group of pixels of a feed fiber, a seed fiber, and a molten zone formed therebetween using a laser beam;
identifying, via the ECU, a feature of interest within the first group of pixels;
locating one or more position-identifying pixels within the feature of interest as a second group of pixels; and
controlling a horizontal position of the feed fiber in real-time via the ECU using the second group of pixels while growing the SCF, including transmitting electronic position control signals to the one or more actuators.

2. The method of claim 1, wherein:
identifying the feature of interest within the first group of pixels includes identifying a saturated pixel cluster within the first group of pixels, the saturated pixel cluster having a threshold brightness level indicative of a location of the molten zone in the first group of pixels;
locating the one or more position-identifying pixels includes identifying a center pixel of the saturated pixel cluster as a reference point; and
controlling a horizontal position of the feed fiber in response to a positional variation of the reference point.

3. The method of claim 2, further comprising:
maintaining a size and/or shape of the molten zone via the electronic position control signals, via the ECU, such that the reference point remains static.

4. The method of claim 2, further comprising:
varying a size and/or shape of the molten zone using the ECU, via control of the laser beam and/or a feed rate of the feed fiber, to thereby form a tapered profile in the fiber.

5. The method of claim 1, wherein:
identifying the feature of interest includes identifying respective edges of the feed fiber and the seed fiber within the first group of pixels;
locating the position-identifying pixels includes using the respective edges to identify a common longitudinal centerline of the feed fiber and the seed fiber; and
controlling the horizontal position of the feed fiber in response to a positional variation of the common longitudinal centerline.

6. The method of claim 5, wherein identifying respective edges of the feed fiber and the seed fiber includes using a Canny edge detection algorithm.

7. The method of claim 1, wherein receiving the set of image data from the at least one digital camera includes using a first camera to image a first optical axis of the feed fiber and a second camera to image a second optical axis of the feed fiber, and wherein the first optical axis of the feed fiber and the second optical axis of the feed fiber are mutually perpendicular.

8. The method of claim 1, further comprising:
receiving, via the ECU, a trigger signal from an external device, wherein the trigger signal is indicative of a requested initiation of a fiber growing process using the fiber growing machine; and
requesting, via the ECU in response to the trigger signal, that the at least one digital camera commences collection of the image data.

9. The method of claim 1, wherein the fiber growth machine includes a translatable platform having a plurality of actuators collectively operable for moving the translatable platform with two horizontal translational degrees of freedom, and wherein controlling the horizontal position of the feed fiber includes controlling the actuators via the electronic position control signals.

10. The method of claim 1, wherein the at least one camera includes a first camera positioned on a first optical axis and operable for collecting portions of the image data on a first optical axis, and a mirror positioned on a second optical axis that is orthogonally arranged with respect to the first optical axis, wherein the first camera is configured to collect another portion of the image data that is reflected off of the mirror.

11. An automated system for monitoring and controlling growth of a single-crystal fiber (SCF), comprising:
a camera configured to output a set of image data inclusive of a first group of pixels of a feed fiber, a seed fiber, and a molten zone, wherein the molten zone is formed between the feed fiber and the seed fiber using a laser beam in a fiber growing machine; and
an electronic control unit (ECU) in communication with the camera, wherein the ECU includes a processor and computer-readable storage medium on which is recorded an instruction set, the instruction set being executable by the processor to cause the ECU to:
identify a feature of interest within the first group of pixels;
locate one or more position-identifying pixels within the feature of interest as a second group of pixels; and
control a horizontal position of the feed fiber using the second group of pixels while the fiber is grown via the fiber growing machine, including transmitting electronic position control signals to one or more actuators of the fiber growing machine.

12. The automated system of claim 11, wherein the instruction set is executable by the processor to cause the ECU to:
identify the feature of interest by identifying a saturated pixel cluster within the first group of pixels, the saturated pixel cluster having a threshold brightness level indicative of a location of the molten zone in the first group of pixels;
locate the position-identifying pixels by identifying a center pixel of the saturated pixel cluster as a reference point;
control the horizontal position of the feed fiber in response to a positional variation of the reference point within the saturated pixel cluster; and
maintain a size and/or a shape of the molten zone via the electronic position control signals such that the reference point remains static.

13. The automated system of claim 11, the instruction set being executable by the processor to cause the ECU to:
form a tapered profile in the SCF by varying a size and shape of the molten zone via control of the laser beam and/or a feed rate of the feed fiber.

14. The automated system of claim 11, the instruction set being executable by the processor to cause the ECU to:
identify the feature of interest by identifying respective edges of the feed fiber and the seed fiber within the first group of pixels;
locate the position-identifying pixels by using the respective edges to identify a common longitudinal centerline of the feed fiber and the seed fiber; and
control the horizontal position of the feed fiber in response to a positional variation of the common longitudinal centerline.

15. The automated system of claim 11, wherein the camera includes a first camera configured to image a first axis of the feed fiber and either (i) a second camera configured to image a second axis of the feed fiber that is orthogonally arranged with respect to the first axis, or (ii) one or more mirrors positioned on the second axis for directing another portion of the image data to the camera, the instruction set being executable by the processor to cause the ECU to:
receive the set of image data from the first camera and the second camera or the one or more mirrors.
